(19) United States
(12) Patent Application Publication
(10) Pub. No.: US 2001/0024868 A1
(43) Pub. Date: Sep. 27, 2001

(54) Microelectronic structure and method of fabricating it

(76) Inventors: Nicolas Nagel, Munchen (DE); Robert Primig, Munchen (DE); Igor Kasko, Munchen (DE); Rainer Bruchhaus, Yokohama (JP)

Correspondence Address: LERNER AND GREENBERG, P.A., POST OFFICE BOX 2480, hollywood, FL, 33022-2480, US

(21) Appl. No.: 09/729,069

(22) Filed: Dec. 4, 2000

(30) Foreign Application Priority Data
Dec. 2, 1999 (DE) 199 58 200.9

(51) Int. Cl. C30B 1/00

(52) U.S. Cl. 438/496

(57) ABSTRACT

A microelectronic structure has an adhesion layer which is disposed between a base substrate and a barrier layer. The adhesion layer improves the adhesion of the barrier layer on the base substrate, in particular to insulation layers provided there. Microelectronic structures of this type are preferably used in semiconductor memories. A method of fabricating such a microelectronic structure is also provided.

### BACKGROUND OF THE INVENTION

1. Field of the Invention

The invention lies in the field of semiconductor technology and relates to a microelectronic structure having a base substrate and at least one barrier layer above the base substrate, and also to a method of fabricating such a microelectronic structure.

In order to increase the storage capacity of semiconductor memories, the use of so-called high-ε dielectrics (ε>20) or ferroelectric dielectrics is desirable. The preferred materials for this purpose require oxygen-containing atmospheres and temperatures of up to 800° C. during their deposition and conditioning. Under these conditions, however, rapid oxidation of the materials used hitherto for electrodes is to be expected. The use of oxidation-resistant electrode materials was therefore proposed. An important example for such a material is platinum. When platinum is used, however, a problem arises, because at the high process temperatures interfering platinum silicide is formed where the platinum and the silicon are in direct contact. Moreover, oxygen can diffuse relatively easily through platinum and oxidize the silicon situated underneath. For these reasons, a barrier is necessary between the platinum electrode and a polysilicon-filled contact hole which connects the electrode to a selection transistor.

The barrier should meet in particular the following requirements. On the one hand, it must prevent the diffusion of silicon from the contact hole to the platinum electrode and, on the other hand, prevent a diffusion of oxygen from the platinum to the contact hole, in order to preclude the electrically insulating oxidation of silicon. Furthermore, the barrier itself must remain stable under the process conditions.

One possible configuration for a microelectronic structure mentioned above in the form of an electrode barrier system is described in U.S. Pat. No. 5,581,439, for example, where a titanium nitride layer, which prevents the diffusion of silicon, is buried in a silicon nitride layer, which protects at least the titanium nitride layer laterally against oxidation. Seated on the silicon nitride collar there is a palladium base body with a platinum coating, which together form the electrode. At the same time, the titanium nitride layer is intended to be protected against oxidation at least by the palladium. The configuration of a further electrode barrier system with other materials, on the other hand, is described in the technical article by J. Kudo et al., “A High Stability Electrode Technology for Stacked SrBi₂Ta₂O₉ Capacitors Applicable to Advanced Ferroelectric Memory”, IEDM 1997, pp. 609 to 612. The configuration disclosed therein prefers a barrier made of tantalum silicon nitride which is covered by a pure iridium layer and an iridium dioxide layer. The tantalum silicon nitride barrier prevents the diffusion of silicon but must itself be protected against oxidation. This task is performed by the iridium dioxide layer and the pure iridium layer. It has been shown, however, that at high temperatures, in particular at 800° C., the pure iridium layer forms iridium silicide with the tantalum silicon nitride barrier, the iridium silicide being a poor electrical conductor.

The same problems also arise in the configuration favored by Saenger et al., “Buried, self-aligned barrier layer structures for perovskite-based memory devices including Pt or Ir bottom electrodes on silicon-contribution substrates”, J. Appl. Phys. 83(2), 1998, pp. 802-813. This technical article reveals that an interfering iridium silicide forms from pure iridium and polysilicon during an annealing step in a nitrogen atmosphere. Therefore, this siliconization is to be prevented by complete oxidation of the iridium through the use of a preceding annealing step in an oxygen-containing atmosphere. A drawback is that this annealing step in an oxygen-containing atmosphere can be controlled only with difficulty, in particular with regard to the deep oxidation of the iridium, so that if the iridium layer has a non-uniform layer thickness, the polysilicon may also be oxidized, thereby interrupting the electrical contact between polysilicon and the iridium.

The use of a deposited pure iridium layer with a subsequent oxygen treatment is likewise disclosed in the technical article by Jeon et al., “Thermal stability of Ir/polycrystalline-Si structure for bottom electrode of integrated ferroelectric capacitors”, Appl. Phys. Lett. 71(4), 1997, pp. 467-469. The use of iridium dioxide as a barrier, on the other hand, is described by Cho et al., “Preparation and Characterization of Iridium Oxide Thin Films Grown by DC Reactive Sputtering”, Jpn. J. Appl. Phys. 36, 1997, pp. 1722-1727. The use of a multilayer system including platinum, ruthenium and rhenium, on the other hand, is disclosed by Onishi et al., “A New High Temperature Electrode-Barrier Technology On High Density Ferroelectric Capacitor Structure”, IEDM 96, pp. 699-702; Bhatt et al., “Novel high temperature multilayer electrode-barrier structure for high-density ferroelectric memories”, Appl. Phys. Lett. 71(5), 1997, S. 719-721; Onishi et al., “High Temperature Barrier Electrode Technology for High Density Ferroelectric Memories with Stacked Capacitor Structure”, Electrochem. Soc. 145, 1998, pp. 2563-2568; Aoyama et al., “Interfacial Layers between Si and Ru Films Deposited by Sputtering in Ar/O₂ Mixture Ambient”, Jpn. J. Appl. Phys. 37, 1998, pp. L242-L244.

A further barrier is proposed in U.S. Pat. No. 5,852,307, which describes the use of a slightly oxidized ruthenium layer and a ruthenium dioxide layer.

With all the conventional barrier layers, however, there is the risk that, at the required high process temperatures, in particular in the course of a thermal step required for conditioning the high-ε materials or the ferroelectric materials, the barrier layers will no longer be sufficiently stable or become detached from their support.

### SUMMARY OF THE INVENTION

It is accordingly an object of the invention to provide a microelectronic structure which overcomes the above-mentioned disadvantages of the heretofore-known structures of this general type and which is sufficiently stable even at temperatures of up to 800° C. and which has firmly adhering barrier layers. It is a further object of the invention to provide a method of fabricating such a structure.

With the foregoing and other objects in view there is provided, in accordance with the invention, a microelectronic structure, including:

a base substrate;

at least one barrier layer provided over the base substrate; and

an adhesion layer disposed between the base substrate and the at least one barrier layer, the adhesion layer containing at least one of titanium, zirconium, hafnium, cerium, tantalum, vanadium, chromium, niobium, tantalum nitride, titanium nitride, tantalum silicide nitride and tungsten silicide.

In other words, the object of the invention is achieved, in the case of a microelectronic structure of the type mentioned in the introduction, by virtue of the fact that an adhesion layer is provided between the base substrate and the barrier layer, the adhesion layer containing at least one material from the group including titanium, zirconium, hafnium, cerium, tantalum, vanadium, chromium, niobium, tantalum nitride (TaNₓ), titanium nitride (TiNₓ), tantalum silicide nitride (TaSiₓN_{y}) and tungsten silicide (WSiₓ). In particular, the nitrides and silicides mentioned may be present either in stochiometric or non-stochiometric form.

With the objects of the invention in view there is also provided, a microelectronic structure, including:

a base substrate at least partly composed of an insulating material and formed with an opening;

the opening completely penetrating through the insulating material;

at least one conductive material filling the opening and terminating flush with the insulating material;

a barrier layer disposed on the base substrate, the barrier layer including an iridium dioxide layer and an oxygen-containing iridium layer;

the oxygen-containing iridium layer being a sputtered layer produceable at a temperature of at least 250° C. in an atmosphere containing by volume between 2.5% and 15% of oxygen;

an adhesion layer disposed over the opening and directly between the base substrate and the barrier layer, the adhesion layer containing at least one material selected from titanium, zirconium, hafnium, cerium, tantalum, vanadium, chromium, niobium, tantalum nitride, titanium nitride, tantalum silicide nitride and tungsten silicide; and

a noble metal layer disposed on the barrier layer.

With the objects of the invention in view there is further provided, a microelectronic structure, including:

a base substrate at least partly composed of an insulating material and formed with an opening;

the opening completely penetrating through the insulating material;

at least one conductive material filling the opening and terminating flush with the insulating material;

a metal silicide layer disposed over the opening and directly on the base substrate;

a barrier layer disposed above the metal silicide layer, the barrier layer including an iridium dioxide layer and an oxygen-containing iridium layer;

the oxygen-containing iridium layer being a sputtered layer produceable at a temperature of at least 250° C. in an atmosphere containing by volume between 2.5% and 15% of oxygen;

an adhesion layer disposed directly between the metal silicide layer and the barrier layer, the adhesion layer containing at least one material selected from titanium, zirconium, hafnium, cerium, tantalum, vanadium, chromium, niobium, tantalum nitride, titanium nitride, tantalum silicide nitride and tungsten silicide; and

a noble metal layer disposed on the barrier layer.

The barrier layer can be stabilized through the use of such adhesion layers, so that the barrier layer has sufficient adhesion to its support, generally to the base substrate. Sufficient adhesion is thereby ensured even at temperatures of up to 800° C. The adhesion layer should preferably be provided completely between the barrier layer and the base substrate in order thus to provide a uniform material base for the barrier layer. This ensures reliable adhesion of the barrier layer on different materials of the base substrate.

In general, the base substrate is at least partly composed of an insulating material and has at least one opening, which completely penetrates through the insulating material of the base substrate. This opening is filled with at least one conductive material. The adhesion layer is preferably provided directly on the the conductive material. The opening in the insulating material of the base substrate preferably constitutes a contact hole reaching down to a monocrystalline semiconductor material. As a result, the base substrate includes at least the semiconductor material, the insulating material and the filled opening therein, the insulating material being provided in the form of an insulation layer on the semiconductor material.

The direct contact between the barrier layer and the conductive material is generally provided by the adhesion layer. This has the advantage that the barrier layer is not modified chemically by the conductive material and the barrier properties of the barrier layer are thereby preserved. If the barrier layer laterally covers the opening in the base substrate, it is recommendable to form the adhesion layer at least to the same extent, so that the barrier layer is seated exclusively on the adhesion layer and not on the base substrate itself.

The opening is preferably filled with a silicon-containing material, for example polysilicon or a metal silicide. The opening is furthermore preferably filled with two different materials, in which case polysilicon is preferably situated in the lower region of the opening and a metal silicide layer in the upper region. It is likewise preferred to fill the opening completely with polysilicon or another material and to cover the opening with a metal silicide layer. The metal silicides used are preferably silicides from the group including yttrium silicide, titanium silicide, zirconium silicide, hafnium silicide, vanadium silicide, niobium silicide, tantalum silicide, chromium silicide, molybdenum silicide, tungsten silicide, iron silicide, cobalt silicide, nickel silicide, palladium silicide, platinum silicide and copper silicide. The metal and the silicon may be present in different stochiometric ratios in this case. Furthermore, the metal silicides used may also have a ternary structure and satisfy the general form MSiN, where M denotes a metal and N denotes nitrogen.

The insulating material of the base substrate is preferably composed of silicon oxide or silicon nitride or a layer combination of these materials.

The barrier layer preferably has an oxygen-containing iridium layer and, if appropriate, additionally an oxygen barrier layer. In this case, the oxygen-containing iridium layer prevents diffusion of silicon from the silicon-containing material situated in the opening into the oxygen barrier layer and into further layers that may be provided above the latter. For this purpose, the oxygen-containing iridium layer has a certain proportion of oxygen which prevents the formation of iridium silicide and hence the further diffusion of silicon. Furthermore, the interface between the oxygen-containing iridium layer and the silicon-containing material remains free of iridium silicide to the greatest possible extent even at temperatures of at least up to 800° C. This can be demonstrated for example by resistance measurements on the oxygen-containing iridium layer. The absence of iridium silicide is manifested for example in a very low resistivity of the oxygen-containing iridium layer of less than 100 μOhm*cm, preferably even less than 30 μOhm*cm. With the presence of iridium silicide, which has a very high resistivity of about 6 μOhm*cm, the resistivity of the structure formed from the silicon-containing layer and the oxygen-containing iridium layer would be distinctly above 100 μOhm*cm. The low electrical resistance of the microelectronic structure is a major advantage in particular in very large scale integrated semiconductor components, in particular in semiconductor memories having feature sizes of 0.25 μm or less.

An oxygen-containing iridium layer having the properties described above can be fabricated for example through the use of a sputtering process in an oxygen-containing atmosphere with a small proportion of oxygen, the proportion by volume of oxygen in the atmosphere being between 2.5% and 15%. The limited proportion by volume of oxygen in the atmosphere means that oxygen is also incorporated in the iridium layer only to a certain degree, so that one may also talk of a partially oxidized iridium layer. The proportion by volume of oxygen in the atmosphere is preferably about 5%.

It has been shown in experiments that the oxygen-containing iridium layers fabricated with a proportion by volume of about 2.5% oxygen still withstand siliconization to the greatest possible extent, whereas oxygen-containing iridium layers fabricated in an atmosphere having less than 2.5% oxygen already tend distinctly toward siliconization. On the other hand, an oxygen-containing iridium layer deposited at an oxygen volume concentration of at most 15% still does not lead to an interfering oxidation of the silicon-containing layer situated under the oxygen-containing iridium layer.

In order to further improve the adhesion of the oxygen-containing iridium layer, it is favorable for the oxygen-containing iridium layer to be deposited at a temperature of at least 250° C. In principle, the deposition temperature should be chosen to be high enough to ensure sufficient adhesion to the adhesion layer and, if appropriate, to the base substrate, this enabling an adhesive strength of at least 100 kg/cm² to be achieved.

A further advantage of depositing the oxygen-containing iridium layer at a temperature of at least 250° C. is that there is no need for a further conditioning step for improving the adhesion of the oxygen-containing iridium layer. Provided that the deposition temperature is chosen such that it is not too high, for example between 250° C. and 400° C., structures that have already been produced are hardly subjected to any thermal loading.

The oxygen barrier of the barrier layer advantageously includes a conductive metal oxide, iridium dioxide and ruthenium dioxide, in particular, having proved successful as the metal oxide. The use of these metal oxides also ensures good adhesion of the oxygen barrier layer on the oxygen-containing iridium layer.

It has turned out to be favorable to bury at least the metal silicide layer in the insulating material of the base substrate and to cover it with the adhesion layer. As a result, the silicon-containing material is protected at least laterally by the base substrate against an oxygen attack.

According to another feature of the invention, the at least one barrier layer includes an oxygen barrier layer, and a metal-containing electrode layer covers the oxygen barrier layer.

According to yet another feature of the invention, the adhesion layer is disposed directly on the at least one opening in the base substrate and is disposed partly on the insulating material.

According to another feature of the invention, the at least one conductive material, which is disposed in the at least one opening, has a region contacting the adhesion layer, and the at least one conductive material is composed of at least one metal silicide at least in the region contacting the adhesion layer.

The oxygen-containing iridium layer preferably has a thickness of about 100 nm, expediently even of about 20 to 50 nm. It is desirable to form the oxygen-containing iridium layer such that it is as thin as possible and as much space as possible is saved. The barrier layers (oxygen barrier layer, oxygen-containing iridium layer) contained in the microelectronic structure are advantageously covered by a metal-containing electrode layer. In particular, the oxygen barrier layer should as far as possible be completely coated by the layer. The metal-containing electrode layer is preferably composed of a metal or a noble metal (e.g. platinum, ruthenium, iridium, palladium, rhodium, rhenium, osmium) or of a conductive metal oxide (MOₓ, e.g. ruthenium oxide, osmium oxide, rhodium oxide, iridium oxide, rhenium oxide or conductive perovskites, e.g. SrRuO₃ or (La, Sr)CoO₃. Platinum is particularly preferred as the metal. Situated on the metal-containing electrode layer there is a dielectric, ferroelectric or paraelectric metal-oxide-containing layer (dielectric metal-oxide-containing layer hereinafter), which, in particular in the case of a semiconductor memory, represents the high-ε dielectric or the ferroelectric capacitor dielectric. For the dielectric metal-oxide-containing layer, use is made, in particular, of metal oxides of the general formula ABOₓ or DOₓ, where A denotes, in particular, at least one metal from the group strontium (Sr), bismuth (Bi), niobium (Nb), lead (Pb), zirconium (Zr), lanthanum (La), lithium (Li), potassium (K), calcium (Ca) and barium (Ba), B denotes, in particular, at least one metal from the group titanium (Ti), niobium (Nb), ruthenium (Ru), magnesium (Mg), manganese (Mn), zirconium (Zr) or tantalum (Ta), D denotes titanium (Ti) or tantalum (Ta) and C denotes oxygen. X may be between 2 and 12. Depending on their composition, these metal oxides have dielectric or ferroelectric properties, these properties, if appropriate, being measurable only after a high-temperature step for crystallizing the metal oxides. Under certain circumstances, these materials are present in polycrystalline form, where perovskite-like crystal structures, mixed crystals or superlattices may often be observed. In principle, all perovskite-like metal oxides of the general form ABOₓ are suitable for forming the dielectric metal-oxide-containing layer. Dielectric materials with high ε (ε>20) or materials having ferroelectric properties are, for example, barium strontium titanate (BST, Ba₁₋ₓSrₓTiO₃), niobium-doped strontium bismuth tantalate (SBTN, SrₓBi_{y}(Ta_{z}Nb_{1-z})O₃), strontium titanate (STO, SrTiO₃), strontium bismuth tantalate (SBT, SrₓBi_{y}Ta₂O₉), bismuth titanate (BTO, Bi₄Ti₃O₁₂), lead zirconate titanate (PZT, Pb(ZrₓTi₁₋ₓ)O₃), strontium niobate (SNO, Sr₂Nb₂O₇), potassium titanate niobate (KTN) and lead lanthanum titanate (PLTO, (Pb,La)TiO₃). Furthermore, tantalum oxide (Ta₂O₅) is also used as a high-ε dielectric. Hereinafter dielectric should be understood to mean either a dielectric, paraelectric or ferroelectric layer, so that the dielectric metal-oxide-containing layer may have dielectric, paraelectric or ferroelectric properties.

The microelectronic structure is preferably used in a semiconductor memory device having at least a first and a second electrode and a metal-oxide-containing layer in between, which together form a storage capacitor. In this case, the first electrode of the semiconductor memory device includes at least the oxygen-containing iridium layer and the oxygen barrier layer, so that the first electrode also contains the necessary diffusion barriers in addition to an optional noble metal layer.

With the objects of the invention in view there is also provided, a method of fabricating a microelectronic structure, the method includes the steps of:

providing a base substrate;

applying an adhesion layer on the base substrate, the adhesion layer containing at least one material selected from titanium, zirconium, hafnium, cerium, tantalum, vanadium, chromium, niobium, tantalum nitride, titanium nitride, tantalum silicide nitride and tungsten silicide; and

applying at least one barrier layer on the adhesion layer.

According to another mode of the invention, the adhesion layer is applied with a sputtering process or a chemical vapor deposition process.

According to another mode of the invention, the step of applying the at least one barrier layer includes applying an oxygen-containing iridium layer with a sputtering process in an oxygen-containing atmosphere at a temperature of at least 250° C. and a proportion by volume of oxygen in the atmosphere being between 2.5% and 15%.

According to yet another mode of the invention, the step of applying the at least one barrier layer includes applying an oxygen-containing iridium layer with a sputtering process in an oxygen-containing atmosphere at a temperature of at least 250° C. and a proportion by volume of oxygen in the atmosphere being between 2.5% and 15%; and applying an iridium dioxide layer on the oxygen-containing iridium layer.

According to a further mode of the invention, a metal-containing electrode layer is applied on the barrier layer; and a metal-oxide-containing layer is applied on the metal-containing electrode layer, the metal-oxide-containing layer being a dielectric layer, a ferroelectric layer or a paraelectric layer.

Other features which are considered as characteristic for the invention are set forth in the appended claims.

Although the invention is illustrated and described herein as embodied in a microelectronic structure and method of fabricating it, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWING

FIGS. 1a to 1e are partial, diagrammatic sectional views of structures illustrating individual process steps for fabricating a microelectronic structure;

FIGS. 2a to 2f are partial, diagrammatic sectional views of structures illustrating further process steps for fabricating a microelectronic structure;

FIG. 3 is a partial, diagrammatic sectional view of a microelectronic structure which is a part of a semiconductor memory device;

FIG. 4 is a graph illustrating the specific resistivity of an oxygen-containing iridium layer as a function of a temperature load; and

FIG. 5 is a graph illustrating the specific resistivity of an oxygen-containing iridium layer as a function of the proportion of oxygen in the atmosphere during deposition; and

FIGS. 6 and 7 are graphs illustrating results of x-ray structure examinations on deposited oxygen-containing iridium layers.

### DESCRIPTION OF THE PREFERRED EMBODIMENTS

Referring now to the figures of the drawings in detail, there is shown how, in a first exemplary embodiment, the fabrication of the microelectronic structure proceeds from a base substrate 5 with a layer of silicon dioxide (fabricated for example by deposition using tetraethyl orthosilane (TEOS)) or silicon nitride, through which a contact hole (opening) 10 filled with polysilicon 8 and with a metal silicide 9 penetrates. Consequently, the polysilicon and the metal silicide are buried in the base material. As the metal silicide, use is made, in particular, of silicides from the group including yttrium silicide, titanium silicide, zirconium silicide, hafnium silicide, vanadium silicide, niobium silicide, tantalum silicide, chromium silicide, molybdenum silicide, tungsten silicide, iron silicide, cobalt silicide, nickel silicide, palladium silicide, platinum silicide and copper silicide. However, ternary metal silicides of the general form MSiN are also suitable, where M denotes a metal and N denotes nitrogen. Tungsten, titanium and tantalum silicides are particularly preferred.

The filled contact hole 10 terminates flush with the surface 15 of the base substrate 5. This is achieved for example through the use of a suitable polishing step, for example by chemical mechanical polishing (CMP). An adhesion layer 20 having a thickness of between 10 and 100 nm is subsequently deposited onto the surface 15 of the base substrate 5. Suitable materials for the adhesion layer 20 are, in particular, the materials titanium, zirconium, hafnium, cerium, tantalum, vanadium, chromium, niobium, tantalum nitride (TaN), titanium nitride (TiN), tantalum silicide nitride (TaSiN) or tungsten silicide (WSi). These serve to improve the adhesion to the oxygen-containing iridium layer 25 that is subsequently to be applied.

The adhesion layer 20 improves, in particular, the adhesion between the base substrate 5, in particular to the insulating material of the base substrate 5, and the barrier layer to be applied. This makes it possible to prevent the barrier layer from becoming detached from the insulating material and, as a result, to stabilize the entire microelectronic structure.

The adhesion layer 20 is preferably applied through the use of a sputtering process or through the use of a CVD (chemical vapor deposition) process. Suitable CVD processes are disclosed for example in T. Kodas and M. Hampden-Smith “Chemistry of Metal CVD”, VCH-Weinheim (1994).

An oxygen-containing iridium layer 25 is subsequently applied to the adhesion layer 20 by reactive sputtering of iridium. This is done at a pressure of between 0.005 and 0.02 mbar, preferably at 0.015 mbar, and in an oxygen-argon mixture, the proportion by volume of oxygen being between 2.5% and 15%, preferably 5% (2.5%≦O₂/(O₂+Ar)≦15%). After a sputtering process of about 100 sec, an oxygen-containing iridium layer 25 having a thickness of about 50 to 150 nm has formed, which completely covers the adhesion layer 20. The deposited oxygen-containing iridium layer 25 is highly stable even at very high temperatures and has good adhesion to the adhesion layer 20.

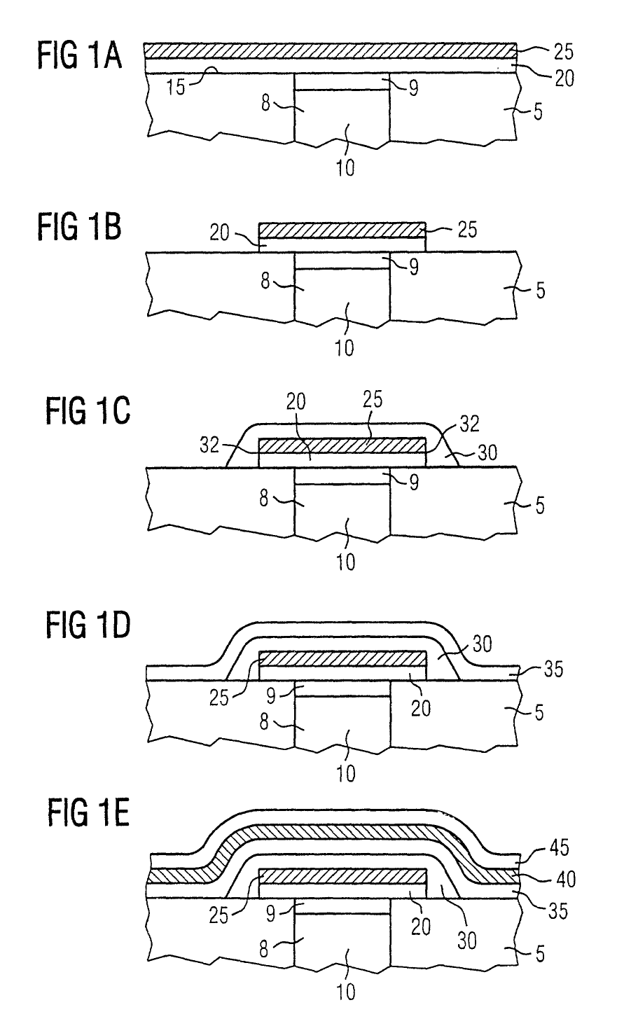

The oxygen-containing iridium layer 25 and the adhesion layer 20 are preferably etched anisotropically, the intention being that after etching the two layers will still project slightly beyond the contact hole 10 laterally, in order to completely cover the polysilicon and metal silicide situated therein. The structure thus obtained is shown in FIG. 1b.

In a further process step as shown in FIG. 1c, an oxygen barrier layer 30 made of iridium dioxide and having a thickness of about 100 nm is applied to the oxygen-containing iridium layer 25 and the base substrate 5 and is etched anisotropically using a mask. In this case, care should preferably be taken to ensure that the iridium dioxide layer 30 completely covers the oxygen-containing iridium layer 25 and the adhesion layer 20 on their side regions 32 as well. This ensures complete protection of the oxygen-containing iridium layer 25 and of the adhesion layer 20 against an oxygen attack, and prevents contact between the oxygen-containing iridium layer 25 and a noble metal layer 35 made of platinum that is subsequently to be applied. The isolation of the oxygen-containing iridium layer 25 from the platinum layer 35 is intended, in particular, to prevent the formation of a platinum-iridium alloy which might possibly lead to unfavorable interface or boundary properties of the platinum layer 35.

A strontium bismuth tantalate layer (SBT) 40 is deposited onto the noble metal layer 35 (illustrated in FIG. 1d), which may optionally also be composed of ruthenium, through the use of an organometallic CVD process or an MOD (metal organic decomposition) process (e.g. spin-on process) using beta-diketonates. This is preferably done at temperatures of between 300 and 800° C. and, in particular in the case of the MOCVD (metal organic chemical vapor deposition) process, in an oxygen-containing atmosphere in order to oxidize the strontium and bismuth beta-diketonates. Finally, a further noble metal layer 45 made of platinum is applied over the whole area. The SBT layer 40 forms the dielectric metal-oxide-containing layer in this exemplary embodiment.

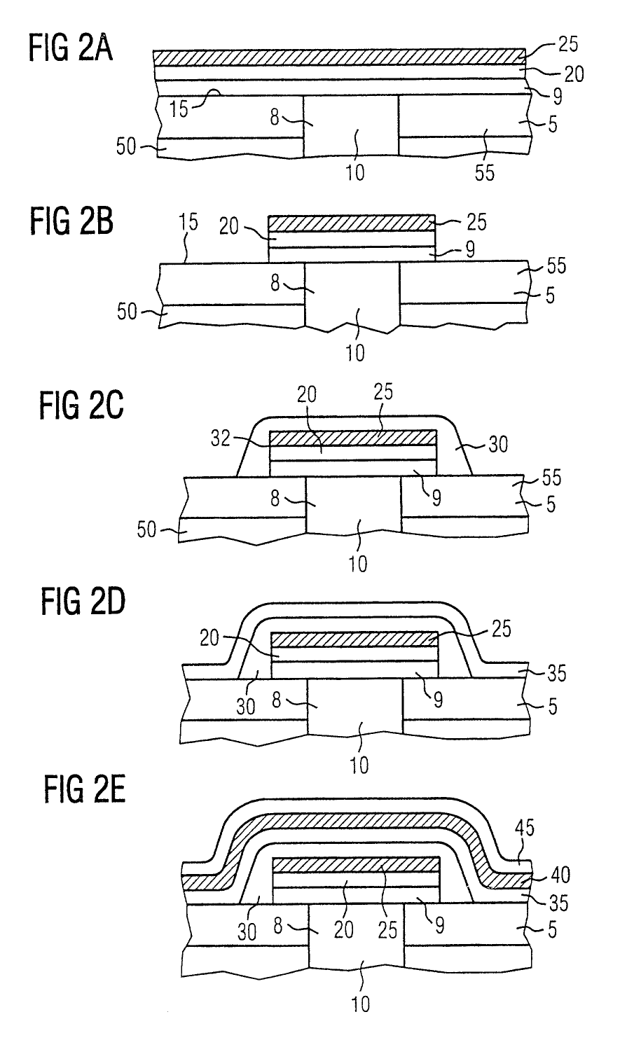

Process steps for fabricating a microelectronic structure with a metal silicide layer on the base substrate in accordance with a further exemplary embodiment are illustrated in FIGS. 2a to 2f. In this case, too, the process proceeds from a base substrate 5, which may optionally also be constructed from two layers. To that end, the base substrate 5 includes a lower silicon dioxide layer 50 with a silicon nitride or TEOS layer 55 situated above it. The base substrate 5 furthermore has a contact hole 10, which is filled with polysilicon up to the surface 15 of the base substrate 5. First of all, after cleaning with hydrofluoric acid, a platinum, titanium or cobalt silicide layer having a thickness of between 30 and 100 nm is applied to this structure illustrated in FIG. 2a.

Afterwards, the adhesion layer 20 and the oxygen-containing iridium layer 25 are applied to the metal silicide layer 9 with a material thickness of between 50 and 150 nm.

In order to further improve the adhesion between the oxygen-containing iridium layer 25 and the adhesion layer 9, it is recommended that the base substrate 5 be heated to at least 250° C. during the deposition of the oxygen-containing iridium layer 25. By way of example, a temperature of about 300° is favorable. At an elevated temperature, moreover, the adhesion of the oxygen-containing iridium layer on the adhesion layer 20 is also improved.

The oxygen-containing iridium layer 25, the adhesion layer 20 and the metal silicide layer 9 are preferably jointly etched anisotropically, thereby forming a layer stack above the contact hole 10.

Afterwards, the oxygen barrier layer 30 made of iridium dioxide is applied and patterned, the layer stack including oxygen-containing iridium layer 25, adhesion layer 20 and metal silicide layer 9 being completely covered by this layer. The noble metal layer 35, the dielectric metal-oxide-containing layer 40 and the further noble metal layer 45 are then also applied and suitably patterned.

There then follows a high-temperature annealing step (e.g. ferroanneal) in an oxygen-containing atmosphere for crystallizing out the dielectric metal-oxide-containing layer 40. This treatment must be carried out at 800° C. for about one hour particularly when SBT is used as the dielectric metaloxide-containing layer 40. During this treatment, the SBT should crystallize out completely in order thus to achieve a maximum remanent polarization of the SBT layer 40. Optionally, the high-temperature annealing step may also precede the deposition of the further noble metal layer 45.

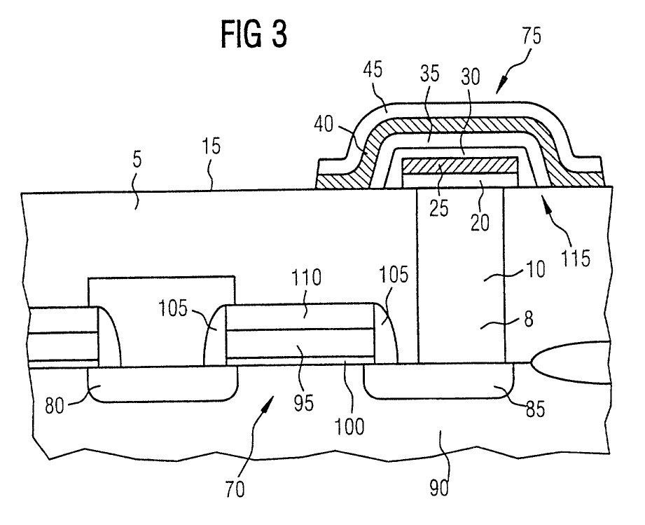

A semiconductor memory device containing the microelectronic structure according to the invention is illustrated in FIG. 3. This device includes a selection transistor 70 and a storage capacitor 75. The selection transistor 70 has two doped regions 80 and 85 isolated from one another in a monocrystalline silicon substrate 90, which represent a source region and a drain region (80, 85) of the selection transistor 70. The gate electrode 95 with gate dielectric 100 beneath it is provided on the silicon substrate 90 between the two doped regions 80 and 85. The gate electrode 95 and the gate dielectric 100 are surrounded by lateral insulation webs 105 and upper insulation layers 110. The entire structure is completely covered by the base substrate 5. A contact hole 10 reaches through the base substrate 5 down to the doped region 85, whereby the storage capacitor 75 seated on the base substrate 5 is connected to the selection transistor.

For its part, the storage capacitor 75 includes a bottom electrode 115, a capacitor dielectric 40 and a top electrode 45. In the present exemplary embodiment, the bottom electrode 115 includes a platinum layer 35, an iridium dioxide layer 30, an oxygen-containing iridium layer 25 and an adhesion layer 20. The bottom electrode 115 is thus constructed in multilayer fashion and also includes all the necessary barrier layers for protecting the polysilicon 8 situated in the contact hole 10 against oxidation, and also for affording protection against undesired diffusion of silicon.

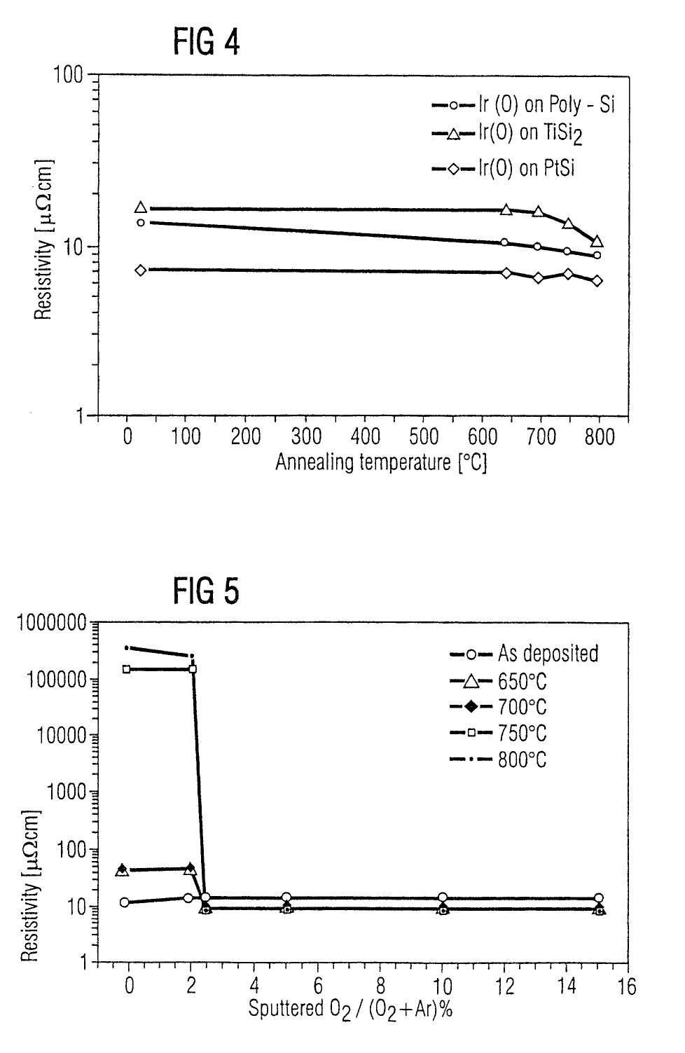

The oxygen-containing iridium layer 25 can be characterized by a very low specific resistivity. This is illustrated in FIG. 4, for example, which shows measurement curves of partially oxidized iridium (oxygen-containing iridium layer indicated by Ir(O)) on various silicon-containing layers. For this purpose, partially oxidized iridium was deposited on polysilicon, titanium silicide and platinum silicide in a 5% oxygen atmosphere and then treated for about 1½ hours at various temperatures. In the temperature range between room temperature and 800° C., the specific resistivity is always less than 20 μOhm*cm, and is even distinctly below 10 μOhm*cm in the case of partially oxidized iridium on platinum silicide.

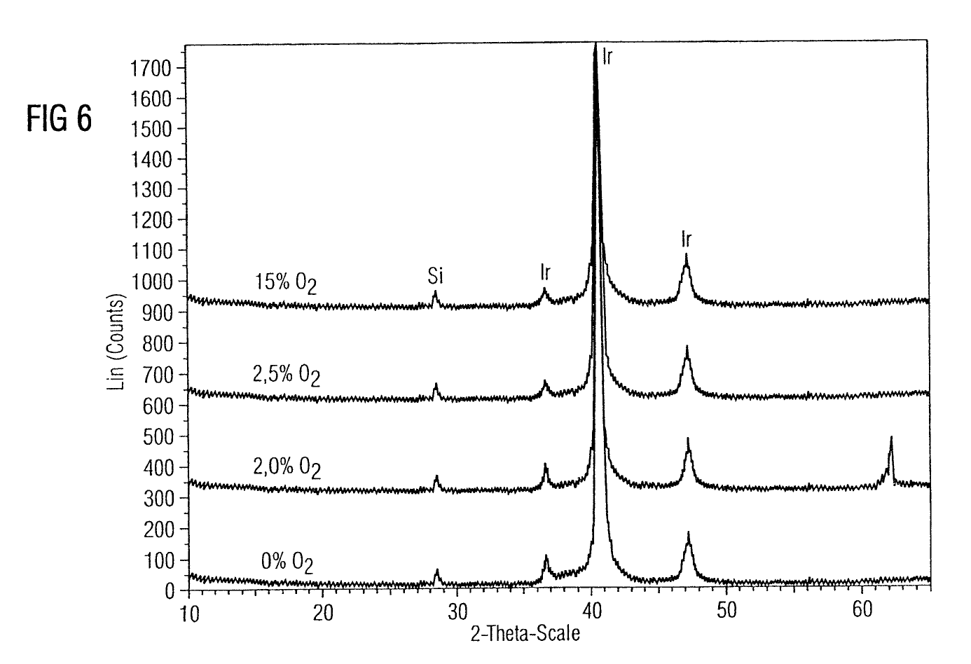

The dependence of the specific resistivity on the oxygen content of the atmosphere during the deposition of the partially oxidized iridium layer is shown in FIG. 5. A sharp drop in resistivity can clearly be seen for a proportion by volume of oxygen of between 2 and 2.5%. Moreover, it can be seen that during a subsequent thermal treatment at relatively high temperatures of between 650 and 800° C., even a further decrease in resistivity must be expected.

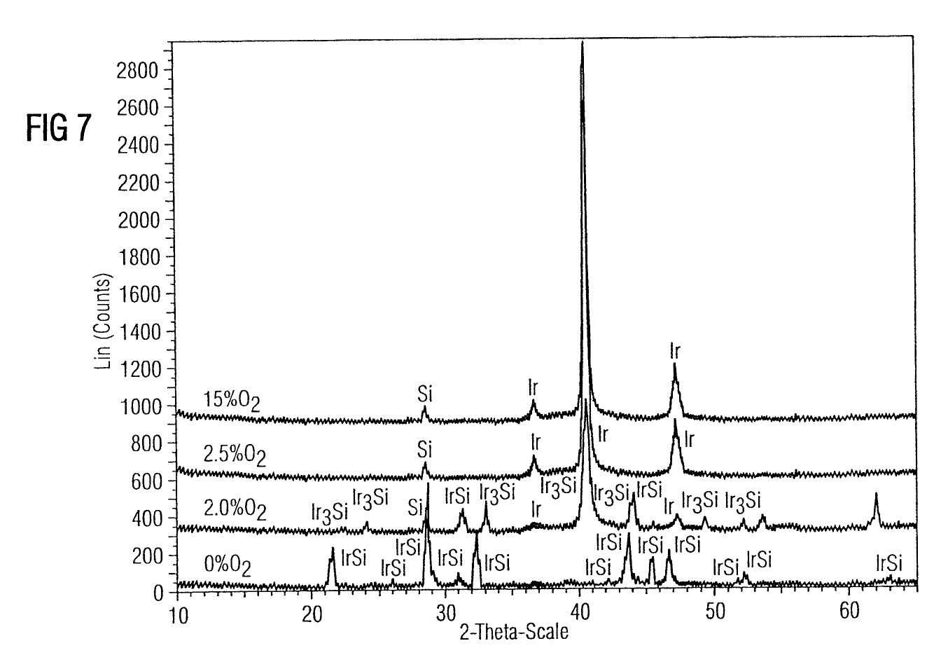

FIGS. 6 and 7 illustrate results of x-ray structure analyses of deposited oxygen-containing iridium layers on polysilicon. FIG. 6 shows results obtained directly after the deposition of the oxygen-containing iridium layer, whereas the results obtained after heat treatment at 700° C. in a nitrogen atmosphere are plotted in FIG. 7. A comparison of FIGS. 6 and 7 clearly shows that no siliciding occurs during a high-temperature treatment in the case of oxygen-containing iridium layers deposited with an oxygen content of at least 2.5%.

Furthermore, the oxygen-containing iridium layer can also be characterized by its relatively low oxygen content. The stochiometric ratios of the oxygen-containing iridium layer clearly differ from these of an iridium dioxide layer (IrO₂). This is manifested e.g. in the fact that the oxygen-containing iridium layer contains more iridium than oxygen.

We claim:

1. A microelectronic structure, comprising:
a base substrate;
at least one barrier layer provided over said base substrate; and
an adhesion layer disposed between said base substrate and said at least one barrier layer, said adhesion layer containing at least one material selected from the group consisting of titanium, zirconium, hafnium, cerium, tantalum, vanadium, chromium, niobium, tantalum nitride, titanium nitride, tantalum silicide nitride and tungsten silicide.

2. The microelectronic structure according to claim 1, wherein:
said base substrate is at least partly composed of an insulating material and is formed with at least one opening;
said at least one opening completely penetrates said insulating material;
at least one conductive material fills said at least one opening; and
said adhesion layer is disposed directly on said at least one conductive material.

3. The microelectronic structure according to claim 2, wherein said adhesion layer is additionally disposed directly on said insulating material.

4. The microelectronic structure according to claim 2, wherein said insulating material is composed of one of silicon nitride and silicon oxide.

5. The microelectronic structure according to claim 1, wherein said at least one barrier layer includes an oxygen-containing iridium layer.

6. The microelectronic structure according to claim 5, wherein said oxygen-containing iridium layer is a sputtered layer produced at a temperature of at least 250° C. in an atmosphere containing by volume between 2.5% and 15% of oxygen.

7. The microelectronic structure according to claim 1, wherein said at least one barrier layer includes an oxygen barrier layer.

8. The microelectronic structure according to claim 7, wherein said oxygen barrier layer is composed of a conductive metal oxide.

9. The microelectronic structure according to claim 8, wherein said conductive metal oxide is composed of one of iridium dioxide and ruthenium dioxide.

10. The microelectronic structure according to claim 1, wherein:
said at least one barrier layer includes an oxygen barrier layer; and
a metal-containing electrode layer covers said oxygen barrier layer.

11. The microelectronic structure according to claim 2, wherein said adhesion layer is disposed directly on said at least one opening in said base substrate and is disposed partly on said insulating material.

12. The microelectronic structure according to claim 11, wherein:
said at least one conductive material disposed in said at least one opening has a region contacting said adhesion layer; and
said at least one conductive material is composed of at least one metal silicide at least in said region contacting said adhesion layer.

13. The microelectronic structure according to claim 1, including a metal silicide layer disposed on said base substrate and directly between said adhesion layer and said opening.

14. The microelectronic structure according to claim 12, wherein said at least one metal silicide contains at least one silicide selected from the group consisting of yttrium silicide, titanium silicide, zirconium silicide, hafnium silicide, vanadium silicide, niobium silicide, tantalum silicide, chromium silicide, molybdenum silicide, tungsten silicide, iron silicide, cobalt silicide, nickel silicide, palladium silicide, platinum silicide and copper silicide.

15. The microelectronic structure according to claim 10, including a metal-oxide-containing layer covering said metal-containing electrode layer, said metal-oxide-containing layer being a layer selected from the group consisting of a dielectric metal-oxide-containing layer, a ferroelectric metal-oxide-containing layer and a paraelectric metal-oxide-containing layer.

16. A microelectronic structure, comprising:
a base substrate at least partly composed of an insulating material and formed with an opening;
said opening completely penetrating through said insulating material;
at least one conductive material filling said opening and terminating flush with said insulating material;
a barrier layer disposed on said base substrate, said barrier layer including an iridium dioxide layer and an oxygen-containing iridium layer;
said oxygen-containing iridium layer being a sputtered layer produceable at a temperature of at least 250° C. in an atmosphere containing by volume between 2.5% and 15% of oxygen;
an adhesion layer disposed over said opening and directly between said base substrate and said barrier layer, said adhesion layer containing at least one material selected from the group consisting of titanium, zirconium, hafnium, cerium, tantalum, vanadium, chromium, niobium, tantalum nitride, titanium nitride, tantalum silicide nitride and tungsten silicide; and
a noble metal layer disposed on said barrier layer.

17. A microelectronic structure, comprising:
a base substrate at least partly composed of an insulating material and formed with an opening;
said opening completely penetrating through said insulating material;
at least one conductive material filling said opening and terminating flush with said insulating material;
a metal silicide layer disposed over said opening and directly on said base substrate;
a barrier layer disposed above said metal silicide layer, said barrier layer including an iridium dioxide layer and an oxygen-containing iridium layer;
said oxygen-containing iridium layer being a sputtered layer produceable at a temperature of at least 250° C. in an atmosphere containing by volume between 2.5% and 15% of oxygen;
an adhesion layer disposed directly between said metal silicide layer and said barrier layer, said adhesion layer containing at least one material selected from the group consisting of titanium, zirconium, hafnium, cerium, tantalum, vanadium, chromium, niobium, tantalum nitride, titanium nitride, tantalum silicide nitride and tungsten silicide; and
a noble metal layer disposed on said barrier layer.

18. A method of fabricating a microelectronic structure, the method which comprises:
providing a base substrate;
applying an adhesion layer on the base substrate, the adhesion layer containing at least one material selected from the group consisting of titanium, zirconium, hafnium, cerium, tantalum, vanadium, chromium, niobium, tantalum nitride, titanium nitride, tantalum silicide nitride and tungsten silicide; and
applying at least one barrier layer on the adhesion layer.

19. The method according to claim 18, which comprises applying the adhesion layer by using a sputtering process.

20. The method according to claim 18, which comprises applying the adhesion layer by using a chemical vapor deposition process.

21. The method according to claim 18, wherein the step of applying the at least one barrier layer includes applying an oxygen-containing iridium layer with a sputtering process in an oxygen-containing atmosphere at a temperature of at least 250° C. and a proportion by volume of oxygen in the atmosphere being between 2.5% and 15%.

22. The method according to claim 18, wherein the step of applying the at least one barrier layer includes:
applying an oxygen-containing iridium layer with a sputtering process in an oxygen-containing atmosphere at a temperature of at least 250° C. and a proportion by volume of oxygen in the atmosphere being between 2.5% and 15%; and
applying an iridium dioxide layer on the oxygen-containing iridium layer.

23. The method according to claim 18, which comprises:
applying a metal-containing electrode layer on the barrier layer; and
applying a metal-oxide-containing layer on the metal-containing electrode layer, the metal-oxide-containing layer being a layer selected from the group consisting of a dielectric layer, a ferroelectric layer and a paraelectric layer.
